(19) United States
(12) Patent Application Publication
(10) Pub. No.: US 2022/0164082 A1
(43) Pub. Date: May 26, 2022

(54) TOUCH MODULE AND ELECTRONIC DEVICE HAVING THE SAME

(71) Applicant: TPK Touch Solutions (Xiamen) Inc., Xiamen (CN)

(72) Inventors: Xian Bin Xu, Xiamen City (CN); Chun Chi Lin, Yunlin County (TW); Xuefen Wang, Taoyuan City (TW); Weichou Chen, Taoyuan City (TW)

(21) Appl. No.: 17/102,531

(22) Filed: Nov. 24, 2020

(51) Int. Cl. G06F 3/041; H05K 1/18; H01L 51/52

(52) U.S. Cl. CPC G06F 3/04164; H01L 27/32; H01L 51/5281; H05K 1/189

(57) ABSTRACT

A touch module includes a sensing element, a circuit element, and an optical element. The sensing element has a sensing circuit and a first connecting zone. The sensing circuit extends to the first connecting zone. The circuit element has a first conductive portion. The sensing circuit extending to the first connecting zone is electrically connected with the first conductive portion. The optical element has a connecting notch. The sensing element is disposed on the optical element. The first connecting zone corresponds to the connecting notch. The sensing circuit extending to the first connecting zone is exposed from the optical element.

### BACKGROUND

### Technical Field

The present disclosure relates to touch sensing devices.

### Description of Related Art

With the advantages of bright colors and low energy consumption, light-emitting diode (LED) display devices and organic light-emitting diode (OLED) display devices have been widely used in the daily lives of people. Since organic light-emitting diode (OLED) display devices can be bent, these display devices have become one of the main technologies applied to the curved display devices and flexible display devices.

Since touch sensing technology has also become one of the main input interfaces for people to operate electronic devices such as computers, mobile phones, or tablet computers, display modules nowadays are often required to be designed with touch functions. However, as the functional requirements are continuously increased, the layers to be stacked for the display modules of these electronic devices are also required to be continuously increased, which leads to a continuous increase in the manufacturing difficulty. Therefore, how to produce flexible touch display devices which can provide good visual effect has become one of the problems that people having ordinary skill in the art work hard to solve.

### SUMMARY

A technical aspect of the present disclosure is to provide a touch module, which has an improved transmission performance of sensing signals and is able to avoid rupture of a transmission route.

According to an embodiment of the present disclosure, a touch module includes a sensing element, a circuit element, and an optical element. The sensing element has a sensing circuit and a first connecting zone. The sensing circuit extends to the first connecting zone. The circuit element has a first conductive portion. The sensing circuit extending to the first connecting zone is electrically connected with the first conductive portion. The optical element has a connecting notch. The sensing element is disposed on the optical element. The first connecting zone corresponds to the connecting notch. The sensing circuit extending to the first connecting zone is exposed from the optical element.

In one or more embodiments of the present disclosure, the touch module further includes a first conductive connecting layer. The first conductive connecting layer is disposed on the first connecting zone and is electrically connected with the first conductive portion. A first distribution zone of the first conductive connecting layer on the sensing element is free from overlap with a second distribution zone of the optical element on the sensing element.

In one or more embodiments of the present disclosure, the first conductive connecting layer includes an anisotropic conductive adhesive.

In one or more embodiments of the present disclosure, the sensing element includes a first surface and a second surface. The first surface and the second surface face away from each other. The sensing element further has a second connecting zone. The first connecting zone is located at an edge of the first surface. The second connecting zone is located at an edge of the second surface. The first connecting zone and the second connecting zone at least partially overlap with each other.

In one or more embodiments of the present disclosure, the touch module further includes a second conductive connecting layer. The second conductive connecting layer is disposed on the second connecting zone. The circuit element includes at least one second conductive portion. The second conductive portion is electrically connected with the second conductive connecting layer.

In one or more embodiments of the present disclosure, the second conductive connecting layer includes an anisotropic conductive adhesive.

In one or more embodiments of the present disclosure, the touch module further includes a display element. The display element is disposed at a side of the sensing element away from the optical element.

In one or more embodiments of the present disclosure, the display element is an organic lighting emitting diode display element.

In one or more embodiments of the present disclosure, the optical element is a circular polarizer.

According to an embodiment of the present disclosure, an electronic device includes any one of the touch modules above.

As mentioned above, the touch module of the embodiment of the present disclosure includes the optical element, and the first connecting zone of the sensing element is located at the connecting notch. Thus, the sensing element, the first conductive connecting layer and the circuit element can have a proper electrical connection through thermal compression, such that the touch module provides a proper transmission route for sensing signals.

### BRIEF DESCRIPTION OF THE DRAWINGS

The disclosure can be more fully understood by reading the following detailed description of the embodiments, with reference made to the accompanying drawings as follows:

FIG. 1 is an exploded view of a touch module according to an embodiment of the present disclosure;

FIG. 2 is a front view of a sensing element according to an embodiment of the present disclosure;

FIG. 3 is a top view of the touch module according to an embodiment of the present disclosure;

FIG. 4 is a bottom view of the touch module according to an embodiment of the present disclosure;

FIG. 5 is an exploded view of a touch module according to another embodiment of the present disclosure;

FIG. 6 is a front view of a sensing element according to a further embodiment of the present disclosure;

FIG. 7 is a top view of the touch module according to an embodiment of the present disclosure;

FIG. 8 is a bottom view of the touch module according to an embodiment of the present disclosure;

FIG. 9 is a side view of the touch module according to an embodiment of the present disclosure;

FIG. 10 is a bottom view of the touch module according to an embodiment of the present disclosure; and

FIG. 11 is a bottom view of the touch module according to an embodiment of the present disclosure.

### DETAILED DESCRIPTION

The touch module of the embodiment of the present disclosure can be used in light-emitting diode display devices and organic light-emitting diode display devices, and the type of display device is not intended to limit the present disclosure. The touch module of the embodiment of the present disclosure can provide a proper transmission route for sensing signals.

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure and should not be interpreted in an idealized or overly formal sense unless expressly so defined herein.

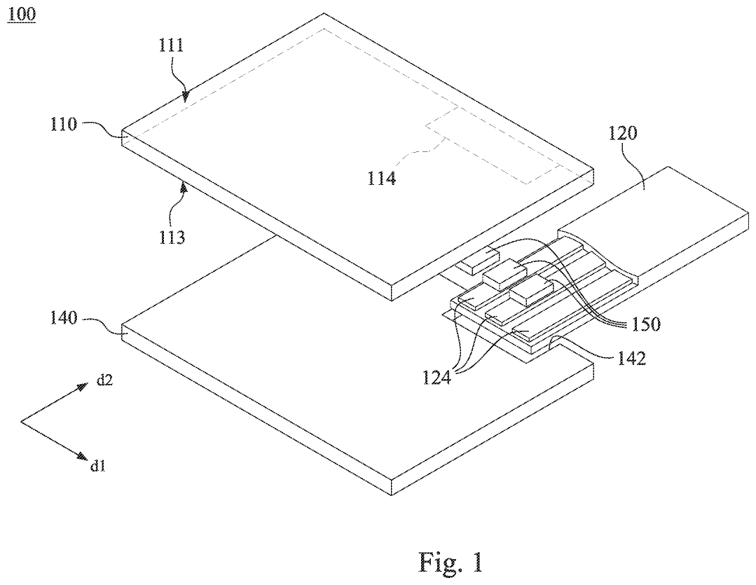

Reference is made to FIG. 1. FIG. 1 is an exploded view of a touch module 100 according to an embodiment of the present disclosure. In this embodiment, as shown in FIG. 1, the touch module 100 includes a sensing element 110, a circuit element 120, and an optical element 140. The optical element 140 is a soft material, such as polymer film or liquid crystal material. In the integration of sensing element 110, the circuit element 120, and the optical element 140, if the optical element 140 has low physical strength, bonding failure between the sensing element 110 and the circuit element 120 may result because external force, such as compression force, may not transfer to the bonding area efficiently. Conventionally, greater compression force may be applied to the bonding area to make a stable bonding structure. However the greater force may result in the rupture of conductive electrodes, such as rupture of a peripheral route PL of the sensing circuit.

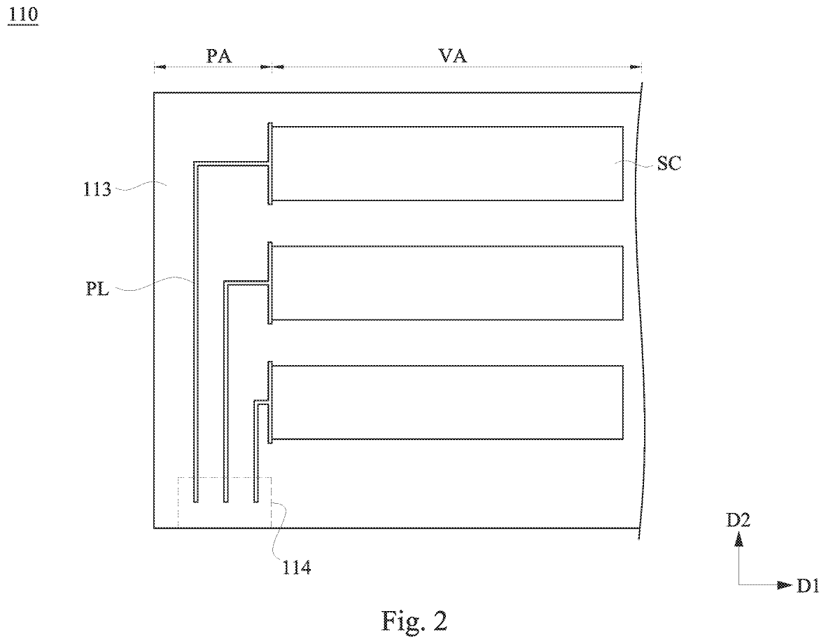

Reference is made to FIG. 2. FIG. 2 is a front view of the sensing element 110 according to an embodiment of the present disclosure. In this embodiment, as shown in FIG. 2, the sensing element 110 is a touch sensing element. The sensing element 110 includes a sensing circuit (including a sensing electrode SC and the peripheral route PL as mentioned below) disposed on a second surface 113, and the sensing circuit may be a transparent conductive electrode or a transparent conductive film after having been patterned. In some embodiments, the sensing circuit is flexible, rollable, or bendable. The sensing circuit can be a touch sensing electrode formed by patterning a conductive thin film having metal nanowires or having metal lines in the form of grids. In some embodiments, the sensing circuit can be formed by patterning a transparent conductive film of, for example, indium tin oxide (ITO), indium zinc oxide (IZO), cadmium tin oxide (CTO), or aluminum-doped zinc oxide (AZO). The term of “metal nanowires” adopted in the present disclosure is a collective noun, and the term refers to a collection of metal wires including multiple-element metals, metal alloys, or metal compounds (including metal oxides). The quantity of the metal nanowires included does not affect the scope of protection as claimed in the present disclosure. At least one of the sectional dimensions (i.e., a diameter of the sectional area) of a singular metal nanowire is less than about 500 nm, preferably less than about 100 nm, and more preferably less than about 50 nm. The metal nanostructure referred to as “wire” in the present disclosure mainly has a high aspect ratio, such as between 10 and 100,000. To be more specific, the aspect ratio (length to diameter of the sectional area) of the metal nanowire can be larger than about 10, preferably more than about 50, and more preferably more than about 100. The metal nanowires can be any type of metal including (but not limited to) silver, gold, copper, nickel, or gilded silver. Other terms, such as silk, fiber, tube, etc., having the same dimensions and high aspect ratios as mentioned above, are also covered by the scope of the present disclosure.

The layer of metal nanowires can include silver nanowires layer, gold nanowires layer, copper nanowires layer, etc. The specific practice of the present disclosure is as follows: disposing a dispersion liquid or an ink having metal nanowires on a substrate of the sensing element 110 by a method of coating, and drying to make the metal nanowires cover a surface of the substrate to form the metal nanowires layer. After the procedures of solidification and drying as mentioned above, substances in the ink, such as solvent, are volatilized. The metal nanowires are distributed on the surface of the substrate in a random manner, and the metal nanowires can contact with each other to provide continuous current paths, which can then form a conductive network. Afterwards, the patterning of the metal nanowires layer is carried out to manufacture the sensing circuit.

In addition, a film can be coated on the metal nanowires layer to form a composite structure having some specific chemical, mechanical, and optical properties, such as providing an adhesion between the metal nanowires and the substrate, or preferably physical mechanical strength. Thus, the film can also be referred to as matrix. Furthermore, some specific polymers can be used to manufacture the film, such that the metal nanowires have additional protection on the surface against scratching and wearing. In such condition, the film can also be referred to as hard coat or overcoat, which adopts materials like polyacrylate, epoxy resin, polyurethane, polysiloxane, and poly (silicon-acrylic), such that the metal nanowires have a higher surface strength in order to increase the resistance to scratching. Moreover, ultra-violet (UV) stabilizers are added to the film in order to increase the resistance of the metal nanowires to ultra-violet. However, the description above only describes the possibility of other additional functions/names of the film and is not intended to limit the present disclosure.

Moreover, FIG. 2 shows a one-sided form of the sensing element 110, in which a plurality of sensing electrodes SC are arranged on the second surface 113 of the sensing element 110 in a parallel manner. The sensing electrodes SC are substantially located at a visible area VA. The sensing electrodes SC are connected to the peripheral routes PL located at a peripheral area PA. The ends of the peripheral routes PL extend to a second connecting zone 114, so as to connect with the circuit element 120 (please refer to FIG. 1). When a user touches the sensing element 110, through the corresponding value of capacitance released from the sensing electrode SC and transmitted to the external controller (not shown) through the circuit element 120, the position that the user touches and a gesture of the user can be calculated. For the sake of convenient illustration, the sensing electrodes SC and the peripheral routes PL can be integrally regarded as the sensing circuit of the sensing element 110.

To be specific, the sensing element 110 includes a substrate, on which the sensing electrodes SC and the peripheral routes PL can be disposed. The sensing element 110 can substantially include the visible area VA and the peripheral area PA. In detail, the sensing electrodes SC used to sense the touching or the gesture of the user is substantially located at the visible area VA. The sensing electrode SC can be made from the metal nanowires as mentioned above. The peripheral routes PL used to transmit signals, such as the sensing signal or a control signal, is substantially located at the peripheral area PA. The peripheral routes PL can be made from the metal nanowires as mentioned above and/or metal (such as copper, silver, etc.). In detail, as shown in FIG. 2, the peripheral area PA at least has the second connecting zone 114 on the second surface 113. The second connecting zone 114 is adjacent to the edge of the substrate. One end of each of the peripheral routes PL is electrically connected with the corresponding sensing electrode SC, while another end extends to the second connecting zone 114. The end of each of the peripheral routes PL extending to the second connecting zone 114 can be disposed with a connecting portion, such as a soldering pad (not shown), which can be electrically connected to an electric circuit (i.e., the conductive portion) on the circuit element 120 in order to transmit signals.

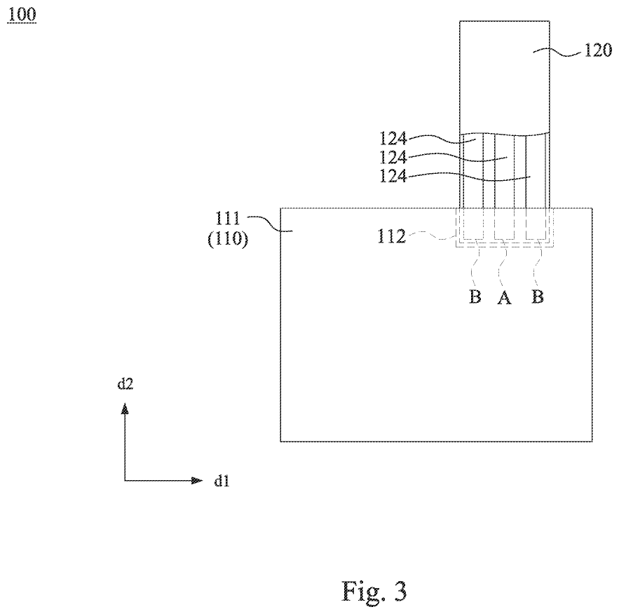

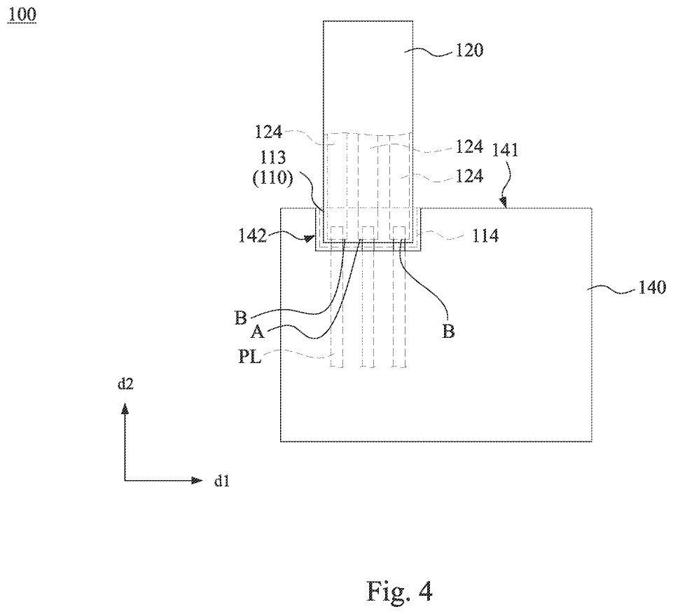

Reference is made to FIGS. 3-4. FIG. 3 is a top view of the touch module 100 according to an embodiment of the present disclosure, which is also a front view of a first surface 111. FIG. 4 is a bottom view of the touch module 100 according to an embodiment of the present disclosure, which is also a front view of the second surface 113. In this embodiment, as shown in FIGS. 1-4, the first surface 111 and the second surface 113 face away from each other. A first connecting zone 112 is defined on the first surface 111. The second connecting zone 114 is defined on the second surface 113. To be specific, the first connecting zone 112 is adjacent to the edge of the first surface 111. The second connecting zone 114 is adjacent to the edge of the second surface 113. The first connecting zone 112 and the second connecting zone 114 at least partially or substantially overlap with each other. As shown in FIGS. 3-4, the position of the first connecting zone 112 on the first surface 111 substantially matches with the position of the second connecting zone 114 on the second surface 113. In this embodiment, the sensing electrodes SC and the peripheral routes PL are disposed on the second surface 113 (for the sake of simplification, the sensing electrodes SC are not shown in FIG. 4). The sensing element 110 is disposed on the optical element 140, and the second surface 113 of the sensing element 110 faces toward the optical element 140. In another embodiment, the sensing electrodes SC and the peripheral routes PL are disposed on the first surface 111 of the sensing element 110, and the first surface 111 faces in a direction away from the optical element 140. In other words, the sensing element 110 is a one-sided sensing stackup, and the position thereof can be selected such that the sensing electrode SC is disposed on the surface facing toward the optical element 140 or on the surface facing away from the optical element 140. The position of the circuit element 120 is not limited, and in this embodiment, the surface of the substrate on which the circuit element 120 is arranged depends on the position of the sensing electrodes SC.

The circuit element 120, for example, includes a flexible printed circuit (FPC). The circuit element 120 can include at least one conductive portion. The conductive portion is disposed with a connecting pad (also known as a soldering pad), which is used to connect with the sensing element 110 to achieve signal transmission. In this embodiment, the circuit element 120 includes three sets of second conductive portions 124 for corresponding to the three sets of peripheral routes PL (the quantity mentioned here is only illustrative, and is not intended to limit the present disclosure) of the sensing element 110. In this embodiment, the second connecting zone 114 of the sensing element 110 can form a soldering zone. For example, second conductive connecting layers 150 (please refer to FIG. 1) are disposed on the second connecting zone 114. Through the second conductive connecting layers 150, the peripheral routes PL of the sensing element 110 are electrically connected with the connecting pads on the second conductive portions 124 to achieve signal transmission. It is worth noting that, a first distribution zone of the second conductive connecting layers 150 on the sensing element 110 is free from overlap with a second distribution zone of the optical element 140 on the sensing element 110. In other words, on top or bottom view, the second conductive connecting layers 150 do not overlap with the optical element 140. In one embodiment, conductive adhesive, such as anisotropic conductive adhesive (ACF), can be used to form the second conductive connecting layers 150.

The optical element 140 includes at least one connecting side 141, and the optical element 140 has a connecting notch 142 located on the connecting side 141. Reference is made to FIG. 1 and FIG. 4. At least one of the purposes of the connecting notch 142 is to expose the second connecting zone 114 in order to define a space. Due to the space defined by the connecting notch 142, the peripheral routes PL, the adhesive (e.g., the second conductive connecting layers 150), and the soldering pads of the circuit element 120 can be efficiently bonded together. As such, problems associated with bonding failures resulting in poor contact or poor connection between the peripheral routes PL, the second conductive connecting layers 150, and the soldering pads of the circuit element 120 in the thermal compression thermal equipment due to the properties of the optical element 140 are avoided. In other words, the dimension and the location of the connecting notch 142 of the optical element 140 correspond to the second connecting zone 114 in order to expose the second connecting zone 114 of the sensing element 110. Therefore, as viewed from the visual angle of FIG. 4, the locations of the mutually glued together connections between the second conductive portions 124 of the circuit element 120 and the peripheral routes PL of the sensing element 110 are located at the connecting notch 142 and are not blocked by the optical element 140 (as viewed from the visual angle of the second surface 113), while other parts of the peripheral routes PL and the sensing electrodes SC are blocked by the optical element 140 (as viewed from the visual angle of the second surface 113). In this way, when the upper and the lower compressing heads of the thermal equipment operate, the upper compressing head can exert a force on the first surface 111 of the sensing element 110, while the lower compressing head avoids the optical element 140 and directly exerts a force on the second conductive portions 124, the second conductive connecting layers 150, and the peripheral routes PL. Thus, the upper and the lower compressing heads can exert properly and efficiently predetermined pressure and heat on the second conductive portions 124, the second conductive connecting layers 150, and the peripheral routes PL, forming a proper glued structure. In other words, a desired bonding/connection is formed between the conductive portions, the conductive connecting layers, and the corresponding peripheral routes. Conventionally, when there is problem of poor contact or poor connection, the applied pressure can be increased in order to achieve a better effect of contact, but the problem of rupture of elements or electrodes may occur. Therefore, the embodiment of the present disclosure can avoid adopting the operation of pressure increment, and thus the problem of rupture of elements or electrodes as mentioned above can be avoided.

The dimension and shape of the connecting notch 142 is not intended to limit the present disclosure. Any dimension and shape of the connecting notch 142 achieving the effect of defining a space as mentioned above is within the scope of the present disclosure.

Furthermore, as viewed from the visual angle of FIG. 3, the location of the mutually glued together connections between the second conductive portions 124 of the circuit element 120 and the peripheral routes PL of the sensing element 110 is visually blocked by the substrate of the sensing element 110 (as viewed from the visual angle of the first surface 111).

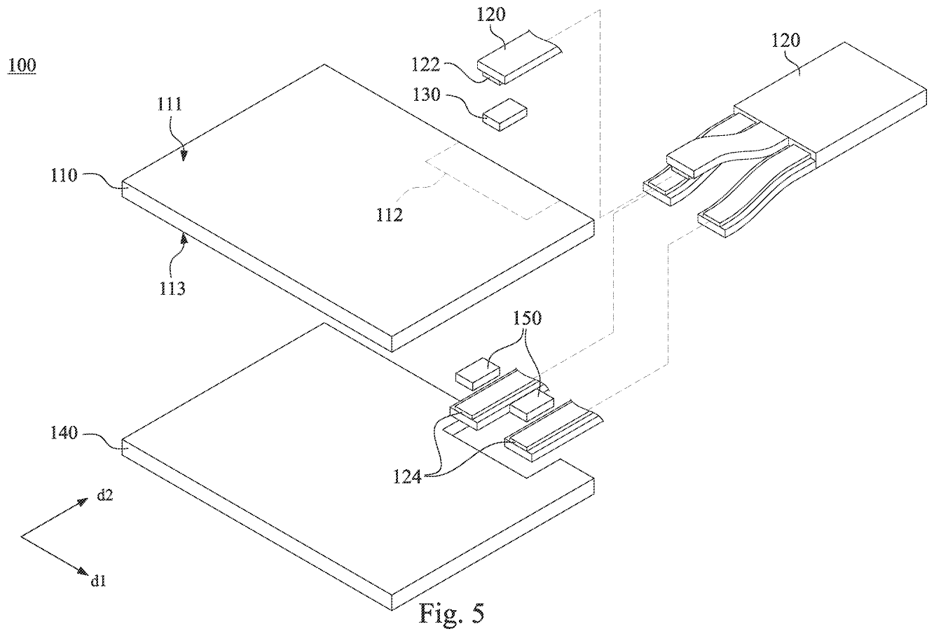

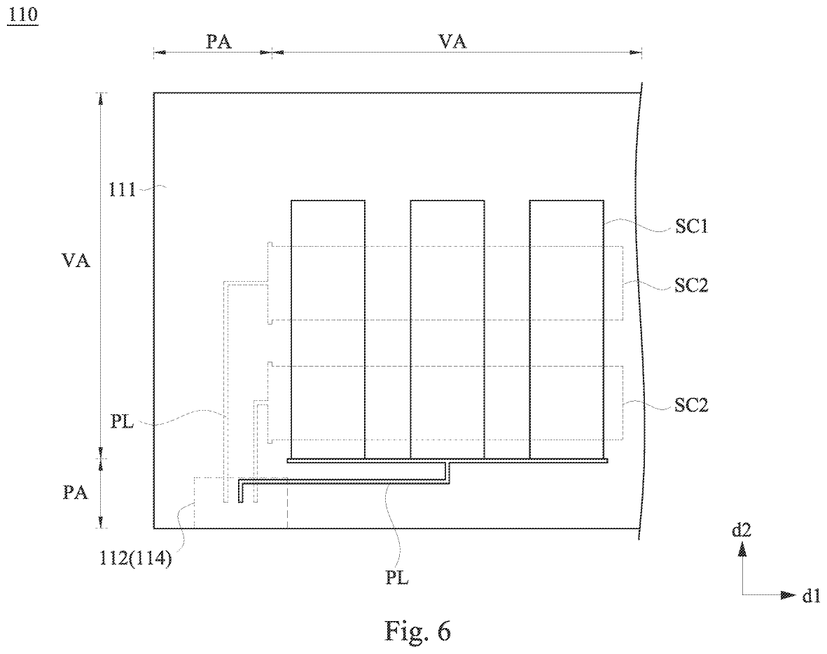

Reference is made to FIGS. 5-6. FIG. 5 is an exploded view of a touch module 100 according to another embodiment of the present disclosure, in which the sensing element 110 is of a double-sided stackup. FIG. 6 is a front view of the sensing element 110 according to a further embodiment of the present disclosure. In this embodiment, as shown in FIGS. 5-6, for example, the sensing element 110 has a plurality of first sensing electrodes SC1 (please refer to FIG. 6) located on the first surface 111 and a plurality of second sensing electrodes SC2 (please refer to FIG. 6) located on the second surface 113. The first surface 111 and the second surface 113 have the peripheral routes PL (please refer to FIG. 6) thereon which respectively connect with the first sensing electrodes SC1 and the second sensing electrodes SC2. In this embodiment, the first sensing electrodes SC1 and the second sensing electrodes SC2 respectively extend along the second direction d2 and the first direction d1 to form their shapes, in which three sets of the first sensing electrodes SC1 and the same peripheral route PL are connected to form a path, while two sets of the second sensing electrode SC2 and the different peripheral routes PL are connected, thus forming two signal paths. The circuit element 120 is connected with these signal paths through ACF during the thermal compression process. Similar to the previous embodiment, the peripheral route PL located on the first surface 111 has an end (i.e., a soldering pad) extending to the first connecting zone 112. This end mutually glues together with the first conductive portion 122 of the circuit element 120 through the first conductive connecting layer 130. Each of the peripheral routes PL located on the second surface 113 has an end (i.e., a soldering pad) extending to the second connecting zone 114. Each of these ends mutually glues together with the corresponding second conductive portion 124 of the circuit element 120 through the corresponding second conductive connecting layer 150. Moreover, the first connecting zone 112 and the second connecting zone 114 have corresponding dimensions and locations, and the optical element 140 has the connecting notch 142 corresponding to the first connecting zone 112/the second connecting zone 114, achieving the effect of providing a way to achieve thermal compression in the manufacturing process. The content of the previous embodiment can be referenced with respect to the elements (such as the first conductive portion 122/the second conductive portion 124, and the first conductive connecting layer 130/the second conductive connecting layer 150) in this embodiment and are not repeatedly described herein.

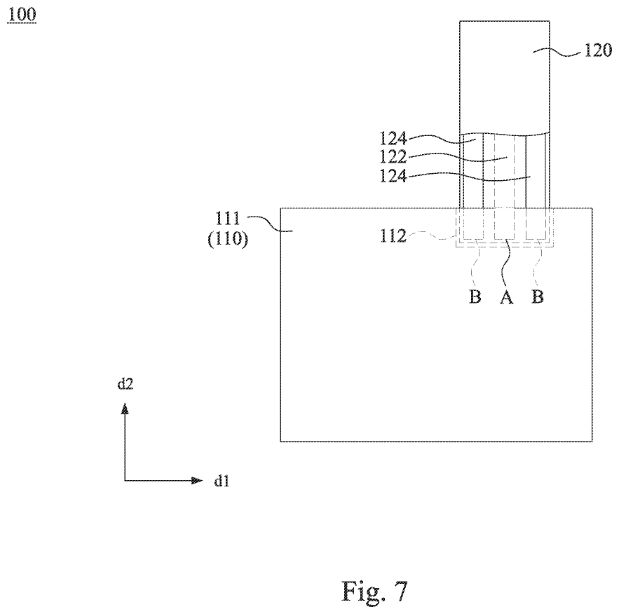

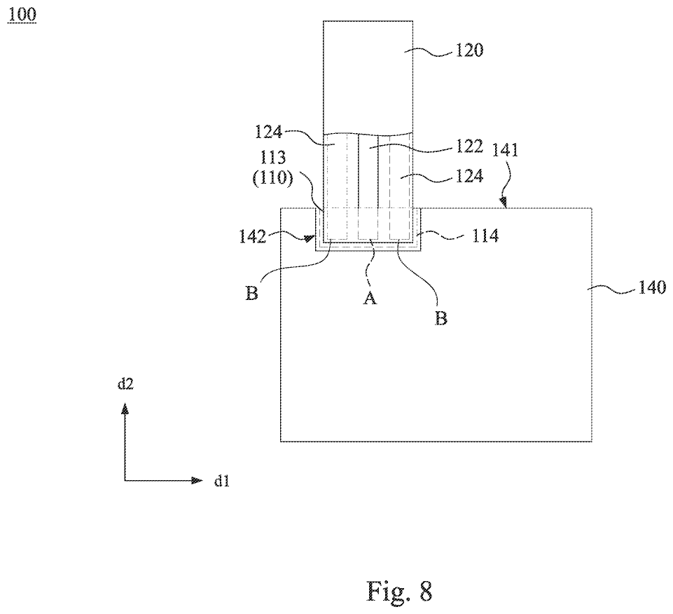

Reference is made to FIGS. 7-8. FIG. 7 is a top view of the touch module 100 according to an embodiment of the present disclosure. FIG. 8 is a bottom view of the touch module 100 according to an embodiment of the present disclosure. In this embodiment, as shown in FIGS. 7-8, the first conductive portion 122 is disposed on a subsidiary zone A within the first connecting zone 112, and the second conductive portions 124 are disposed on subsidiary zones B within the second connecting zone 114. Moreover, the subsidiary zones A, B are mutually staggered from each other. Therefore, the second surface 113 of the sensing element 110 can provide efficient area of force bearing when thermally compressing the first conductive portion 122 and the first conductive connecting layer 130 to transmit the heat and pressure provided by the thermal compression equipment, such that a proper connection by glue is formed between the first conductive portion 122 and the peripheral route PL. Similarly, the first surface 111 of the sensing element 110 can provide efficient area of force bearing when thermally compressing the second conductive portions 124 and the second conductive connecting layers 150, such that a proper connection by glue is formed between the second conductive portions 124 and the peripheral routes PL.

To be specific, the sensing element 110 in this embodiment can be, for example, a capacitive touch sensing element. The first surface 111 of the sensing element 110 can have, for example, a driving signal circuit (i.e., the first sensing electrode SC1). The second surface 113 can have, for example, a sensing signal circuit (i.e., the second sensing electrode SC2). The conductive connecting layers 130/150, for example, have anisotropic conductive adhesives, and the circuit element 120, for example, includes the flexible circuit board. Therefore, by providing the connecting notch 142 as mentioned above, the optical element 140 does not affect the distribution of pressure in the process of thermal compression. Thus, in the process of thermal compression, an end of the peripheral route PL located on the first surface 111 connects with the driving signal circuit, while another end is glued together with the first conductive portion 122 without any defect. Moreover, an end of the peripheral route PL located on the second surface 113 connects with the sensing signal circuit, while another end is glued together with the second conductive portion 124 without any defect. In this embodiment, a glue connection formed without any defect can achieve a better quality of signal transmission.

In other words, apart from providing the connecting notch 142 of the optical element 140, in this embodiment, the distribution zone (i.e., the subsidiary zone A) of the first conductive portion 122/the first conductive connecting layer 130 on the sensing element 110 is free from overlap with the distribution zones (i.e., the subsidiary zones B) of the second conductive portions 124/the second conductive connecting layers 150 on the sensing element 110. Thus, the quality of glue connection of the double-sided sensing element 110 in the process of thermal compression is not affected.

In another embodiment, the subsidiary zones A, B as mentioned above are partially overlapped or completely overlapped with each other.

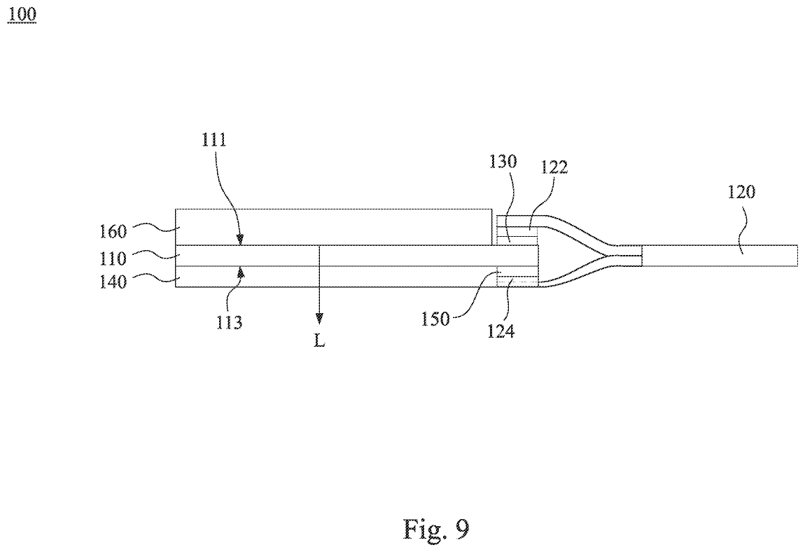

Reference is made to FIG. 9. FIG. 9 is a side view of the touch module 100 according to an embodiment of the present disclosure. In this embodiment, as shown in FIG. 9, the touch module 100 further includes a display element 160. The display element 160 is disposed on the first surface 111 of the sensing element 110 (i.e., disposed at a side of the sensing element 110 away from the optical element 140). The display element 160, for example, can provide an image light L to transmit to the outside through the optical element 140 in order to display an image to the user. The display element 160, for example, can be a liquid crystal display element or an organic light-emitting diode (OLED) display element. An optical transparent glue or other similar adhesives (not shown) can be used between the display element 160 and the sensing element 110 to carry out the adhesion. Moreover, it is shown in FIG. 9 that the first conductive portion 122 and the second conductive portions 124 are structured in a Y shape to respectively connect with the peripheral routes PL on the upper and lower surfaces of the sensing element 110.

Furthermore, the optical element 140 can be a polarizing element, such as a circular polarizer. Thus, when the display element 160 provides the image light L, the optical element 140 can alleviate the problem of reflection of light from the environment. The optical element 140 can be a stretched polarizer or a liquid crystal polarizer. The optical element 140 can include a linear polarizer and a retardation film, in which the retardation film can include a λ/4 film, or the retardation film can be a multilayer structure having a λ/4 film and a λ/2 film. An optical transparent glue or other similar adhesives (not shown) can be used between the optical element 140 and the sensing element 110 to carry out the adhesion. The term “glue layer” or similar terms used in the present disclosure can include bonding layer and tackifying layer. The adhesive layer can be formed from a composition of pressure sensitive adhesive (PSA) or a composition of optically clear adhesive (OCA). The terms “light-transmitting” and “transparent” used in the present disclose mean the penetration rate of light (such as visible light having a wavelength between 400 nm and 700 nm) is larger than 85%, 88%, 90%, 95%, etc. The transparent glue layer/the optical transparent adhesive in this embodiment of the present disclosure can have appropriate adhesive force, such that no delamination, bubbling, peeling, etc., will occur when the optical stack is bent. Moreover, the transparent glue layer can also have certain viscoelasticity, such that the transparent glue layer can be applied in a flexible display. In one embodiment, the transparent glue layer can be formed from acrylic composition. In one embodiment, a liquid crystal composition can be coated on the substrate surface of the sensing element 110/display element 160 to form a liquid crystal polarizer. In other words, the liquid crystal polarizer can directly contact the sensing element 110/display element 160. In one embodiment, the liquid crystal composition can include a reactive liquid crystal compound and a dichroic dye. The reactive liquid crystal composition can further include a solvent, such as propylene glycol monomethyl ether acetate (PGMEA), xylene, methyl ethyl ketone (MEK), chloroform, etc.

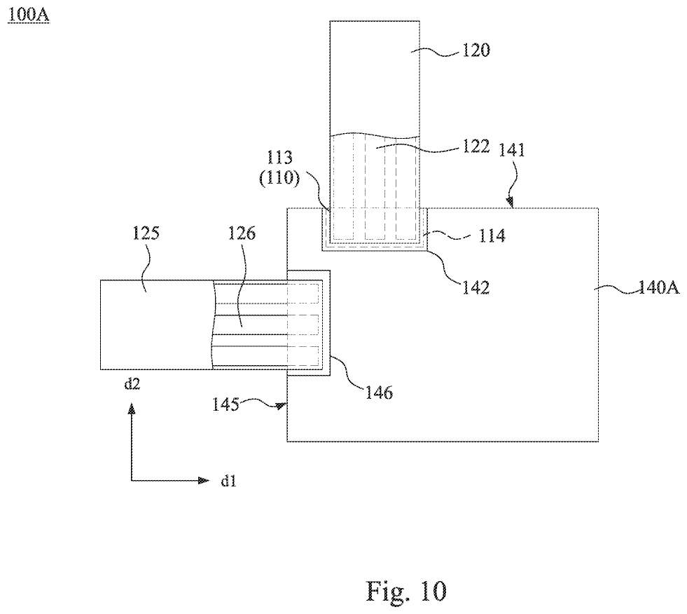

Reference is made to FIG. 10. FIG. 10 is a bottom view of the touch module 100A according to an embodiment of the present disclosure. FIG. 10 shows the front view of the second surface 113 of the sensing element 110 and the optical element 140A. In this embodiment, as shown in FIG. 10, the touch module 100A, being similar to the touch module 100 in the previous embodiment, includes the sensing element 110 and the circuit elements 120/125. The same elements and their detailed description are not repeatedly described herein.

At least one of the differences between the touch module 100A and the touch module 100 is that the touch module 100A includes an optical element 140A which is disposed on the second surface 113. The optical element 140A includes a plurality of connecting notches as mentioned above. To be specific, the optical element 140A has two connecting notches (i.e., the connecting notches 142/146) disposed on the connecting side 141 and the connecting side 145. In other words, in this embodiment, the connecting notches at different positions are used to enable the preferable pattern, under heat and pressure in the process of thermal compression as mentioned above, to achieve a proper connection.

In this embodiment, the connecting side 141 extends along the first direction d1, and the connecting side 145 extends along the second direction d2. The first direction d1 and the second direction d2 are substantially perpendicular with each other. The connecting side 141 and the connecting side 145 are connected to each other. In other words, the connecting position of the first sensing electrodes SC1/the second sensing electrodes SC2 (not shown) of the double-sided sensing element 110 in this embodiment can be disposed at different edges, such that the first sensing electrodes SC1 and the second sensing electrodes SC2 do not influence each other in the process of thermal compression. In this embodiment, two of the circuit elements (i.e., the circuit element 120 and the circuit element 125) can be used to connect with the first sensing electrodes SC1/the second sensing electrodes SC2 as mentioned above. Since the optical element 140A has the connecting notch 142 and the connecting notch 146 located at different edges and staggered from each other, a proper electrical connection between the first conductive portions 122 of the circuit element 120 and the third conductive portions 126 of the circuit element 125 can be formed through thermal compression. The optical element 140A does not influence the effect of connection after thermal compression. To be specific, the first conductive portions 122 can achieve the connections by glue with the peripheral routes PL connected with the second sensing electrodes SC2, while the third conductive portions 126 can achieve the connections by glue with the peripheral routes PL connected with the first sensing electrodes SC1. In another embodiment, the first conductive portions 122 and the third conductive portions 126 belong to the same flexible printed circuit board.

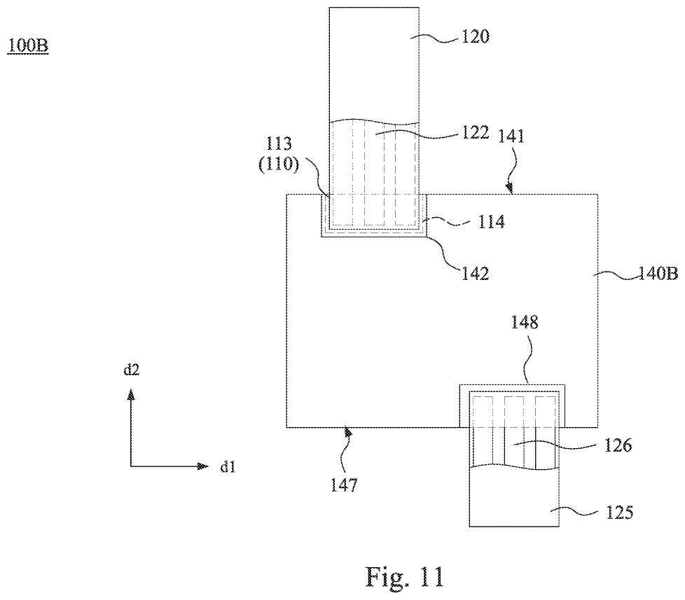

Reference is made to FIG. 11. FIG. 11 is a bottom view of the touch module 1008 according to an embodiment of the present disclosure. FIG. 11 shows the front view of the second surface 113 of the sensing element 110 and the optical element 140B. In this embodiment, as shown in FIG. 11, the touch module 100B is similar to the touch module 100A in the previous embodiment. The same elements and their detailed description are not repeatedly described herein.

At least one of the differences between the touch module 100B and the touch module 100A is that the touch module 100B includes an optical element 140B which is disposed on the second surface 113. The optical element 140B includes a plurality of connecting notches as mentioned above. To be specific, the optical element 140B has two connecting notches (i.e., the connecting notches 142/148) disposed on the connecting side 141 and the connecting side 147. In other words, in this embodiment, the connecting notches at different positions are used to enable the preferable pattern, under heat and pressure in the process of thermal compression as mentioned above, to achieve a proper connection.

In this embodiment, the connecting side 141 and the connecting side 147 extend along the first direction d1. The connecting side 141 and the connecting side 147 are respectively located at two opposite sides of the optical element 140B. In other words, the connecting position of the first sensing electrodes SC1/the second sensing electrodes SC2 (not shown) of the double-sided sensing element 110 in this embodiment can be disposed at different edges, such that the first sensing electrodes SC1 and the second sensing electrodes SC2 do not influence each other in the process of thermal compression. In this embodiment, two of the circuit elements (i.e., the circuit element 120 and the circuit element 125) can be used to connect with the first sensing electrodes SC1/the second sensing electrodes SC2 as mentioned above. Since the optical element 140B has the connecting notch 142 and the connecting notch 148 located at different edges and staggered from each other, a proper electrical connection between the first conductive portions 122 of the circuit element 120 and the third conductive portions 126 of the circuit element 125 can be formed through thermal compression. The optical element 140B does not influence the effect of connection after thermal compression. As shown in FIG. 11, the first conductive portions 122 can achieve the connections by glue with the peripheral routes PL connected with the second sensing electrodes SC2, while the third conductive portions 126 can achieve the connections by glue with the peripheral routes PL connected with the first sensing electrodes SC1. In another embodiment, the first conductive portions 122 and the third conductive portions 126 belong to the same flexible printed circuit board.

In conclusion, the optical element in the embodiment of the present disclosure has a connecting notch. Thus, the conductive portion of the circuit element can be electrically connected with the conductive connecting layer of the sensing element through thermal compression, which is not influenced by the optical element, such that a touch module providing a proper transmission route for sensing signals is provided.

The touch module provided by the embodiment of the present disclosure can be applied to display devices, for example, electronic devices with display panels, such as mobile phones, tablets, wearable electronic devices, televisions, monitors, laptops, electronic books, digital photo frame, navigator, or the like. To be specific, the touch module of the embodiment of the present disclosure can be assembled with other electronic components to form a device/product, such as a display with touch function. For example, the touch module can be connected to the display element (not shown), such as the liquid crystal display element or the organic lighting emitting diode (OLED) display element. Both of them can be connected together by using optical adhesive or other similar adhesives. On the other hand, the touch module of the embodiment of the present disclosure can be applied to electronic equipment such as portable phones, tablets, laptops, car devices (such as dashboards, driving recorders, car mirrors, car windows, etc.), or can also be applied to flexible products, such as wearables devices (including smart bracelets, smart watches, virtual reality devices, glasses, smart clothes, smart shoes, etc.).

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

1. A touch module, comprising:
a sensing element having a sensing circuit, a first connecting zone, and a second connecting zone, wherein:
the sensing circuit extends to the first connecting zone,
the sensing element comprises a first surface and a second surface facing away from each other,
the first connecting zone is located at an edge of the first surface,
the second connecting zone is located at an edge of the second surface,
the first connecting zone and the second connecting zone at least partially overlap with each other;
a circuit element having a first conductive portion and at least one second conductive portion, the sensing circuit extending to the first connecting zone being electrically connected with the first conductive portion;
an optical element having a connecting notch, the sensing element being disposed on the optical element; and
a first conductive connecting layer disposed on the second connecting zone, wherein:
the at least one second conductive portion is electrically connected with the first conductive connecting layer,
the at least one second conductive portion and the first conductive portion do not overlap in a direction perpendicular to the first surface of the sensing element,
the first connecting zone corresponds to the connecting notch, and
the sensing circuit extending to the first connecting zone is exposed from the optical element.

2. The touch module of claim 1, further comprising:
a second conductive connecting layer disposed on the first connecting zone and electrically connected with the first conductive portion, wherein a first distribution zone of the second conductive connecting layer on the sensing element is free from overlap with a second distribution zone of the optical element on the sensing element.

3. The touch module of claim 2, wherein the second conductive connecting layer comprises an anisotropic conductive adhesive.

4. (canceled)

5. (canceled)

6. The touch module of claim 1, wherein the first conductive connecting layer comprises an anisotropic conductive adhesive.

7. The touch module of claim 1, further comprising:
a display element disposed at a side of the sensing element away from the optical element.

8. The touch module of claim 7, wherein the display element is an organic lighting emitting diode display element.

9. The touch module of claim 1, wherein the optical element is a circular polarizer.

10. An electronic device, comprising the touch module of the claim 1.

11. A touch module, comprising:
a sensing element having a first sensing circuit, a first connecting zone, and a second connecting zone, wherein:
the sensing element comprises a first surface and a second surface facing away from each other,
the first connecting zone is located at an edge of the first surface,
the second connecting zone is located at an edge of the second surface,
the first connecting zone and the second connecting zone at least partially overlap with each other;
a circuit element having a first conductive portion and at least one second conductive portion, the first sensing circuit being electrically connected with the first conductive portion through the first connecting zone; and
an optical element having a connecting notch, the sensing element being disposed on the optical element, wherein:
the at least one second conductive portion is electrically connected to the second connecting zone,
the at least one second conductive portion and the first conductive portion do not overlap in a direction perpendicular to the first surface of the sensing element,
the first connecting zone corresponds to the connecting notch, and
the first sensing circuit extending to the first connecting zone is exposed from the optical element.

12. The touch module of claim 11, wherein the at least one second conductive portion and the optical element lie in a same plane extending parallel to the first surface of the sensing element.

13. The touch module of claim 11, wherein:
the at least one second conductive portion comprises a first second conductive portion and a second conductive portion, and
in a projection of the first conductive portion, the first second conductive portion, and the second conductive portion in the direction perpendicular to the first surface of the sensing element, the first conductive portion is between the first second conductive portion and the second conductive portion.

14. The touch module of claim 11, wherein:
the sensing element comprises a second sensing circuit extending to the second connecting zone, and
the at least one second conductive portion is electrically connected to the second sensing circuit through the second connecting zone.

15. The touch module of claim 11, further comprising:
a display element disposed at a side of the sensing element away from the optical element.

16. The touch module of claim 15, wherein the display element is an organic lighting emitting diode display element.

17. The touch module of claim 11, wherein the optical element is a circular polarizer.

18. A touch module, comprising:
a sensing element having a sensing circuit and a connecting zone, the sensing circuit extending to the connecting zone;
a circuit element having a conductive portion, the sensing circuit extending to the connecting zone being electrically connected with the conductive portion; and
an optical element having a connecting notch, the sensing element being disposed on the optical element, wherein:
the connecting zone corresponds to the connecting notch,
the sensing circuit extending to the connecting zone is exposed from the optical element, and
a bottom surface of the conductive portion is co-planar with a bottom surface of the optical element.

19. The touch module of claim 18, further comprising:
a conductive connecting layer disposed on the connecting zone and electrically connected with the conductive portion, wherein:
a combined thickness of the conductive connecting layer and the conductive portion is equal to a thickness of the optical element.

20. The touch module of claim 18, further comprising:
a display element disposed at a side of the sensing element away from the optical element.

21. The touch module of claim 20, wherein the display element is an organic lighting emitting diode display element.

22. The touch module of claim 18, wherein the optical element is a circular polarizer.
